(19) United States
(12) Patent Application Publication
(10) Pub. No.: US 2006/0043555 A1
(43) Pub. Date: Mar. 2, 2006

(54) Sensor package

(76) Inventor: Chung Yuan Liu, Hsinhua (TW)

Correspondence Address: SMITH, GAMBRELL & RUSSELL, LLP, 1850 M STREET, N.W., SUITE 800, WASHINGTON, DC, 20036, US

(21) Appl. No.: 11/003,369

(22) Filed: Dec. 6, 2004

(30) Foreign Application Priority Data
Aug. 24, 2004 (TW) 093125403

(51) Int. Cl. H01L 23/02

(52) U.S. Cl. 257/680

(57) ABSTRACT

An image sensor package includes a bottom substrate, a transparent substrate, a plurality of spacers and adhesive. The bottom substrate includes a plurality of chips, which each includes an active surface and an image sensor disposed on the active surface. The transparent substrate includes a plurality of transparent substrate units which are respectively corresponding to the chips, wherein each transparent substrate unit is disposed above the active surface of the chip and covers the image sensor. The spacers are disposed between the transparent substrate unit and the chip for maintaining a predetermined gap between the transparent substrate unit and the image sensor. Each transparent substrate unit and chip are connected to each other by the adhesive.

This application claims the priority benefit of Taiwan Patent Application Serial Number 093125403, filed Aug. 24, 2004, the full disclosure of which is incorporated herein by reference.

### BACKGROUND OF THE INVENTION

1. Field of the Invention

The present invention generally relates to a sensor package, and more particularly to an image sensor package including a spacer for maintaining a predetermined gap defined between a transparent substrate unit and an image sensor.

2. Description of the Related Art

For image sensors such as complementary metal-oxide semiconductors (CMOS), the manufacturing technology of the image sensors is similar to that of typical semiconductor chips, and the image sensor is a semiconductor mainly made of silicon and germanium elements. The complementary metal-oxide semiconductor includes a N-type metal-oxide semiconductor (NMOS) transistor with negative electricity and a P-type metal-oxide semiconductor (PMOS) transistor with positive electricity. After the light is sensed, two complementary effects of the NMOS and PMOS can be recorded and read as an image. Thus, the semiconductor package including the above-mentioned image sensor is referred to as an image sensor package for transforming a light signal to an electronic signal.

U.S. Patent Publication No. 2003/0057359, entitled “Image Sensor Package Having Optical Element”, is incorporated herein by reference. Referring to FIG. 1, an image sensor package 10 includes a chip, a housing 14, a lens 16, a glass 18 and a substrate 20. The chip 30 is electrically connected to the substrate 20 by using a wire bonding process. The chip 30 has an image sensor 32 located in the housing 14. The housing 14 adheres to the substrate 20 and supports the lens 16 and the glass 18. The housing 14, the glass 18 and the substrate 20 define an enclosing space 12 for accommodating the chip 30. When the light passes through the lens 16 and the glass 18 and illuminates the image sensor 32, the image sensor 32 is affected by the light and transformed to an electronic sign. The substrate 20 is provided with a plurality of metal traces 22, pads 24 and solder balls 26. The solder ball 26 is electrically connected to the chip 30 through the metal trace 22 and the pad 24, and is electrically connected to an external circuit board (not shown) for transmitting the signal of the image sensor 32. However, the image sensor package 10 is restricted in its design because the chip 30 is disposed on the substrate 20 by using the wire bonding process, and thus the entire height (distance between the lens and the substrate) of the image sensor package 10 is too long, such that the volume of the image sensor package 10 will be enlarged. Furthermore, the image sensor package 10 cannot be applied to the mass production with wafer lever, such that the cost of the packaging process is increased and the reliability of package is decreased.

In order to solve the problem for too long in height of the entire image sensor package resulted from wire bonding process, U.S. Pat. No. 6,737,292, entitled “Method of fabricating an image sensor module at the wafer level and mounting on circuit board”, discloses an image sensor module applied to a thin image sensor device, incorporated herein by reference. Referring FIG. 2, a method for fabricating an image sensor package 40 includes the steps of: forming a plurality of image sensors 42 and pads 43 on an active surface of a wafer, wherein the pads 43 are positioned along a peripheral edge of the image sensors 42; forming a plurality of bumps 44 on a transparent substrate, wherein the bumps 44 are corresponding to the pads 43; forming an adhesive layer 46 on the pads 43 or on the bumps 44; adhering the bumps 44 to the pads 43 by using the adhesive layer 46; respectively dicing the wafer and the transparent substrate along a plurality of dicing lines of the backside of the wafer, wherein the diced wafer (i.e. chip 50) and the diced transparent substrate (i.e. transparent substrate unit 48) adhere to each other by means of the adhesive layer 46 so as to form a single image sensor module cell; and mounting image sensor module cell on a flexible printed circuit board 52 so as to form a single image sensor package 40, shown in FIG. 2. However, the bumps and the adhesive layer are only used for electrically connecting the pads to the printed circuit board, but they are not used for controlling the gap between the diced wafer and the diced transparent substrate. Thus, the non-uniform thickness of the adhesive layer located between the diced wafer and the diced transparent substrate affects the optical effect of the image sensor and the emitting light.

Sellcase Company in Israel also develops a wafer-level thin image sensor package. Referring to FIG. 3, a method for fabricating a image sensor package 60 includes the following steps of: forming a plurality of image sensors 62 and pads 63 on an active surface of a wafer, wherein the pads 63 are positioned along a peripheral edge of the image sensors 62; patterning and forming a passivation layer 72 and a pad extended layer 64 on the active surface of the wafer, wherein the passivation layer 72 covers the image sensors 62, and the pad extended layer 64 is electrically connected to the pads 63; disposing a first adhesive layer 66 on the wafer, wherein the first adhesive layer 66 covers the passivation layer 72, the pads 63 and the pad extended layer 64; attaching a first glass substrate to the active surface of the wafer by means of the first adhesive layer 66; grinding the wafer to a predetermined thickness along a back surface of the wafer, and forming a first notch in the back surface of the wafer for exposing out the pad extended layer 64; disposing a second adhesive layer 74 on the back surface of the wafer, wherein the first notch is filled with the second adhesive layer 74; attaching a second glass substrate to the back surface of the wafer by means of the second adhesive layer 74; forming a plurality of barrier pads 78 on the second glass substrate; forming a second notch in the second glass substrate for passing through the wafer and the first and second adhesive layer 66, 74 and exposing out the pad extended layer 64; forming a plurality of external traces 82 on the second notch and the barrier pads 78, wherein a T-contact is formed between the external traces and the pad extended layer 64; forming a solder mask 84 on the external traces 82 and exposing out a part of external traces 82 located on the barrier pads 78; disposing a plurality of solder balls 86 on the barrier pads 78, wherein the solder balls 86 are electrically connected to the external traces 82; and respectively dicing the second glass substrate, the wafer and the first glass substrate along a plurality of dicing lines of the second glass substrate, wherein the diced second substrate (i.e. second substrate unit 76), the diced wafer (i.e. chip 70) and the diced first substrate (i.e. first substrate unit 68) adhere to each other by means of the first and second adhesive layers 66, 74 so as to form a single image sensor package, shown in FIG. 3. However, when the first glass substrate is attached to the wafer, the first adhesive will be pressed and is non-uniform in its thickness. The non-uniform thickness of the first adhesive layer affects the optical effect of the image sensor and the emitting light.

Accordingly, there exists a need for an image sensor package and a method for manufacturing for the same capable of solving the above-mentioned problem.

### SUMMARY OF THE INVENTION

It is an object of the present invention to provide an image sensor package including a spacer capable of controlling a gap between a transparent substrate unit and an image sensor and further maintaining the gap between the transparent substrate unit and the image sensor.

It is another object of the present invention to provide an image sensor package including a gap between a transparent substrate unit and an image sensor, wherein the gap can be in a state of similar vacuum or be filled with one of inert gas, transparent solid material, transparent partly solid material, transparent liquid, adhesive and oil, thereby avoiding the expansion of residual air in the gap between the transparent substrate unit and the image sensor during heating.

It is a further object of the present invention to provide an image sensor package including a spacer for maintaining a predetermined gap between a transparent substrate unit and an image sensor, thereby avoiding the non-uniform thickness of the stuff between the transparent substrate unit and the image sensor.

The present invention provides an image sensor package including a bottom substrate, a transparent substrate, a plurality of spacers and adhesive. The bottom substrate includes a plurality of chips, which each includes an active surface and an image sensor disposed on the active surface. The transparent substrate includes a plurality of transparent substrate units which are respectively corresponding to the chips, wherein each transparent substrate unit is disposed above the active surface of the chip and covers the image sensor. The spacers are disposed between the transparent substrate unit and the chip for maintaining a predetermined gap between the transparent substrate unit and the image sensor. Each transparent substrate unit and chip are connected to each other by the adhesive.

The present invention further provides a method for manufacturing a sensor package, including the following steps of: providing a bottom substrate including a plurality of chips, which each includes an active surface and an image sensor disposed on the active surface; providing a transparent substrate including a plurality of transparent substrate units respective corresponding to the chips, wherein each transparent substrate unit is disposed above the active surface and covers the image sensor; disposing a plurality of spacers and adhesive on one of the transparent substrate and the bottom substrate; attaching the transparent substrate to the active surface of the bottom substrate, wherein the spacers are used for maintaining a predetermined gap defined between the transparent substrate unit and the image sensor; and respectively dicing the transparent substrate and the bottom substrate to be the transparent substrate units and the chips.

According to the image sensor package and the method of the present invention, the image sensor package can be applied to the mass production with wafer lever, such that the cost of the packaging process is decreased, the reliability of package is increased, and the volume of the image sensor package cannot be enlarged. Furthermore, the gap between the transparent substrate unit and the image sensor is controlled by the spacer of the image sensor package of the present invention for maintaining the gap between the transparent substrate unit and the image sensor and further avoiding the affection of the optical effect of the image sensor and the emitting light. The spacers of the image sensor package of the present invention are used for maintaining a predetermined gap between the transparent substrate unit and the image sensor, thereby avoiding the non-uniform thickness of the stuff (one of the inert gas, transparent solid material, transparent partly solid material, transparent liquid, adhesive and oil) located between the transparent substrate unit and the image sensor during pressing. In addition, according to the image sensor package of the present invention, the gap between the transparent substrate unit and the image sensor can be in a state of similar vacuum or be filled with one of the inert gas, transparent solid material, transparent partly solid material, transparent liquid, adhesive and oil, thereby avoiding the expansion of residual air in the gap between the transparent substrate unit and the image sensor during heating and further avoiding the crack of the image sensor package.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a cross-sectional schematic view of an image sensor package in the prior art.

FIG. 2 is a cross-sectional schematic view of another image sensor package in the prior art.

FIG. 3 is a cross-sectional schematic view of a further image sensor package in the prior art.

FIGS. 4a and 4b are cross-sectional and top plan schematic views of an image sensor package according to the first embodiment of the present invention.

FIGS. 5a and 5b are cross-sectional and top plan schematic views of another image sensor package according to the first embodiment of the present invention.

FIGS. 6a to 6d are top plan schematic views of an image sensor package according to the first embodiment of the present invention.

FIGS. 7a to 12b are cross-sectional and top plan schematic views showing a method for manufacturing an image sensor package according to the first embodiment of the present invention.

FIGS. 13a and 13b are cross-sectional and top plan schematic views of an image sensor package according to the second embodiment of the present invention.

FIGS. 14a and 14b are cross-sectional and top plan schematic views of another image sensor package according to the second embodiment of the present invention.

FIGS. 15 to 20b are cross-sectional and top plan schematic views showing a method for manufacturing an image sensor package according to the second embodiment of the present invention.

FIG. 21 is a cross-sectional schematic view of an image sensor package according to the third embodiment of the present invention.

FIG. 22 is a cross-sectional schematic view of an image sensor package according to the fourth embodiment of the present invention.

FIG. 23 is a cross-sectional schematic view of another image sensor package according to the fourth embodiment of the present invention.

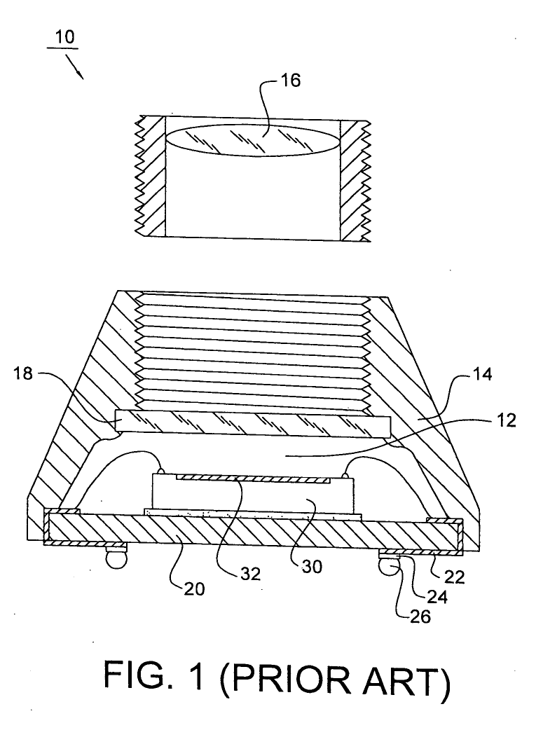

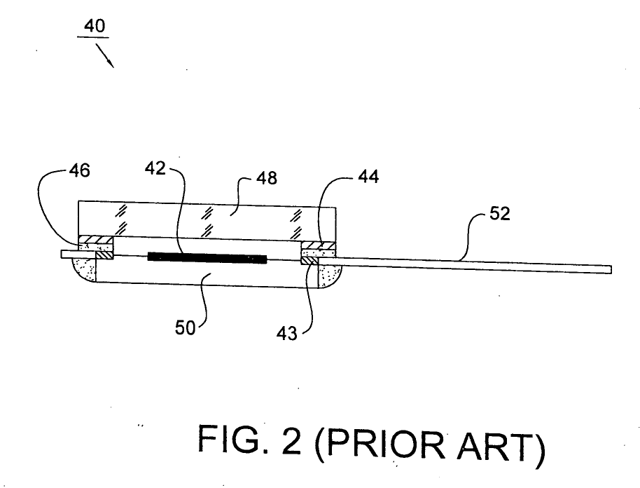

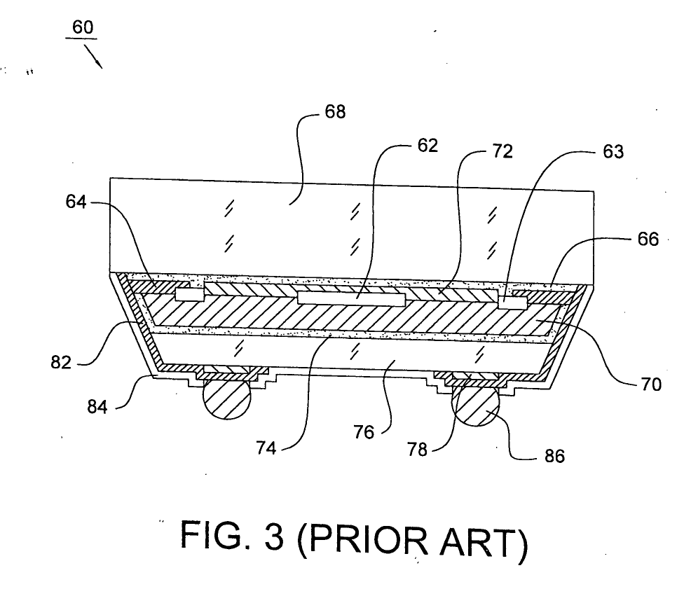

### DETAILED DESCRIPTION OF THE PREFERRED EMBODIMENT

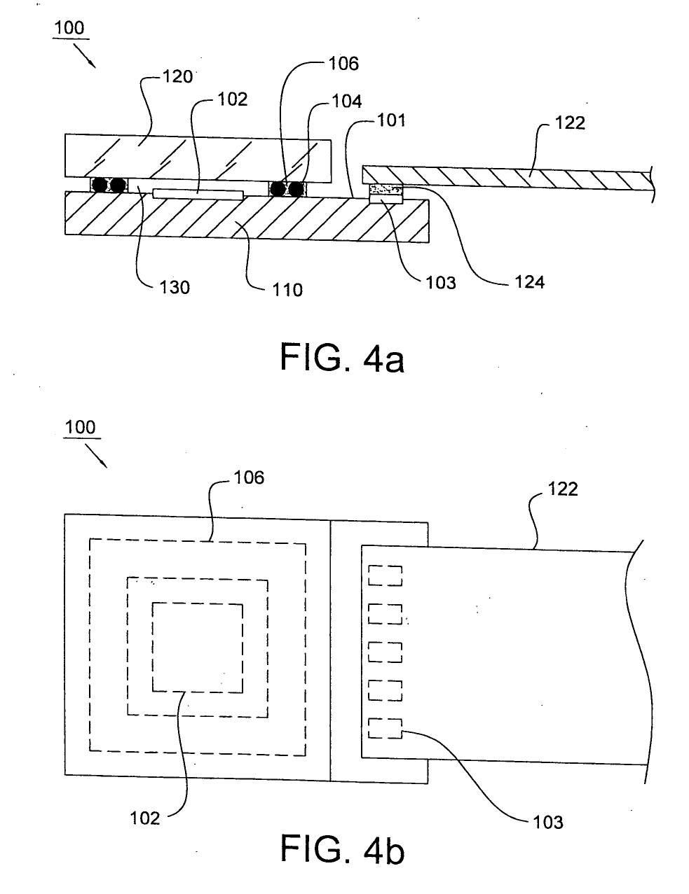

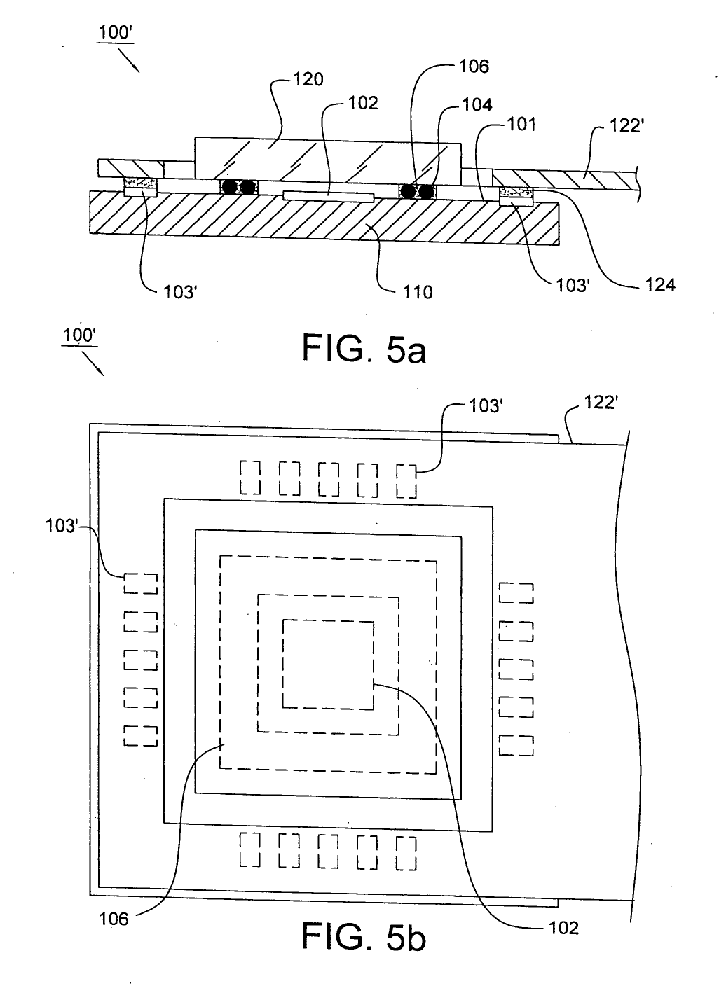

Referring to FIGS. 4a and 4b, they depict an image sensor package 100 according to the first embodiment of the present invention. The image sensor package 100 includes a chip 110, which includes an active surface 101, an image sensor 102 disposed on the active surface 101, and a plurality of pads 103 disposed on the active surface 101, wherein the pads 103 and the image sensor 102 are at the same side. A transparent substrate unit 120 is disposed above the active surface 101 of the chip 110 and covers the image sensor 102. The image sensor 102 can be a complementary metal-oxide semiconductor (CMOS) or charge coupled device (CCD), which made of semiconductor material or organic semiconductor material such as pentacene (C₂₂H₁₄). The chip 110 can be made from a transparent substrate, such as glass, acrylic resin, sapphire, ployimide or silicon wafer. The transparent substrate unit 120 can be made of glass, acrylic resin, sapphire or ployimide materials. A plurality of spacers 104 are disposed between the transparent substrate unit 120 and the chip 110 for maintaining a predetermined gap defined between the transparent substrate unit 120 and the image sensor 102. An adhesive 106 is used for attaching the transparent substrate unit 120 to the chip 110. The pads 103 are mounted and electrically connected to a circuit carrier, such as flexible printed circuit board 122, by using an electrically conductive adhesive 124, such as anisotropic conductive film (ACF). As shown in FIGS. 5a and 5b, it is apparent to one of ordinary skill in the art that the pads 103′ are also located along a peripheral edge of the image sensor 102 and are mounted and electrically connected to another flexible printed circuit board 122′.

The gap between the transparent substrate unit 120 and the image sensor 102 is controlled by the spacers 104 for maintaining the gap between the transparent substrate unit 120 and the image sensor 102 and further avoiding the affection of the optical effect of the image sensor 102 and the emitting light. For example, the predetermined gap can be between 1 and 20 μm. The spacers 104 can be intermixed to the adhesive 106. The spacers 104 can be in the shape of ball (shown in FIG. 4a), fiber (not shown) or bar (not shown), which is made of glass, silicon oxide or plastic material.

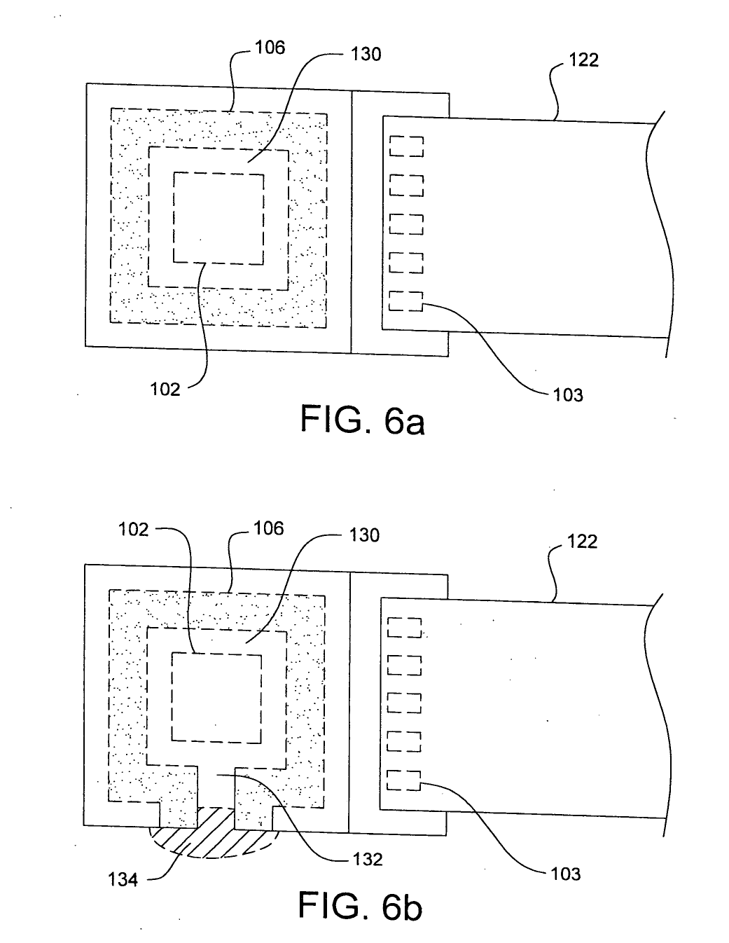

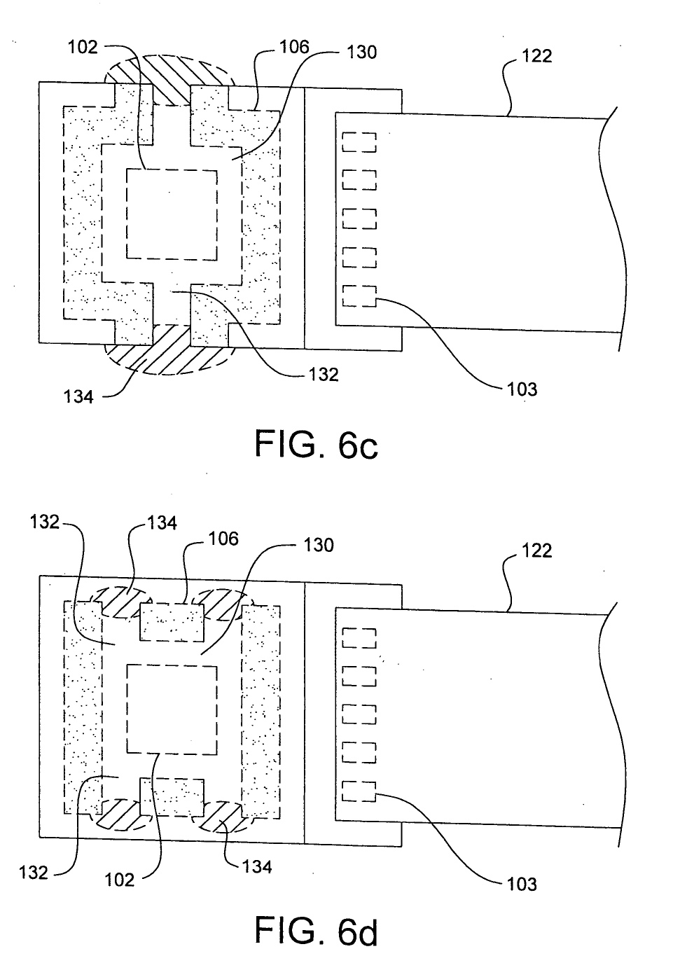

The adhesive 106 can be of annular shape for enclosing the image sensor 102, and the adhesive 106, the transparent substrate unit 120 and the chip 110 define an enclosing space 130. The enclosing space 130 can be closed (shown in FIG. 6a), wherein the enclosing space 130 can be in a state of similar vacuum or be filled with one of inert gas (e.g. Nitrogen), transparent solid material (e.g. UV resin), transparent partly solid material (e.g. liquid crystal), transparent liquid, adhesive and oil. The expansion coefficients of the inert gas, transparent partly solid material, transparent liquid, adhesive and oil are selected to approximate that of the transparent substrate unit 120 and/or the chip 110 if possible, or are low expansion coefficients of material. Also, the enclosing space 130 can include a single opening 132 and a single seal material 134 (shown in FIG. 6b), dual openings 132 and dual seal materials 134 (shown in FIG. 6c) or multiple openings 132 and multiple seal materials 134 (shown in FIG. 6d), wherein the seal material 134 seals the opening 132.

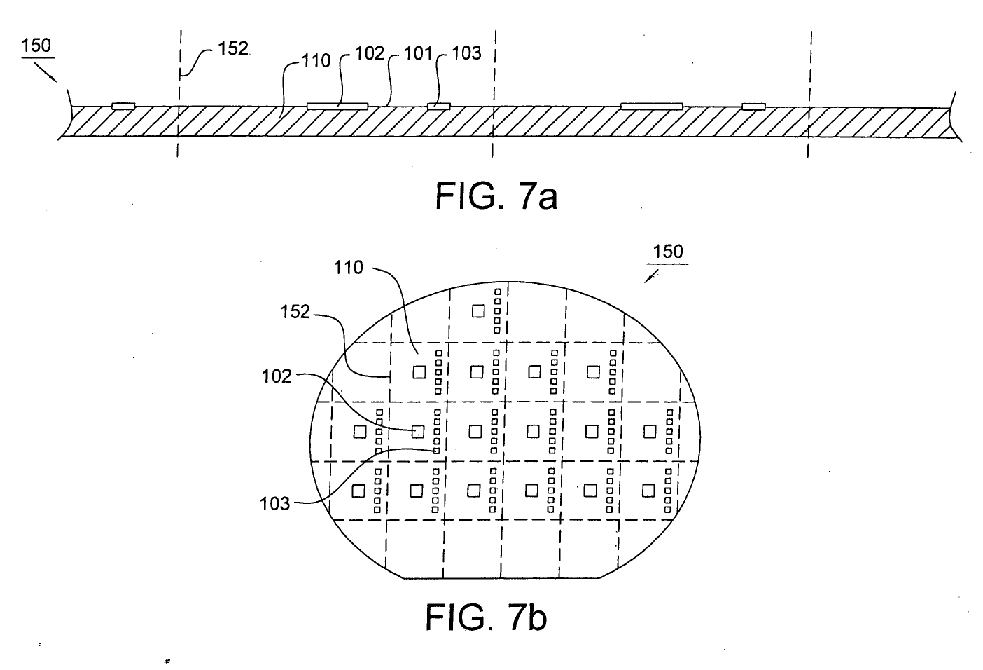

Referring to FIGS. 7a to 12b, they depict a method for manufacturing the image sensor package 100 according to the present invention.

Referring to FIGS. 7a and 7b, a bottom substrate 150 includes a plurality of chips 110, wherein the adjacent chips 110 are separated by a plurality of dicing lines 152. Each chip 110 includes an active surface 101, an image sensor 102 disposed on the active surface 101, and a plurality of pads 103 disposed on the active surface 101, wherein the pads 103 and the image sensor 102 are at the same side.

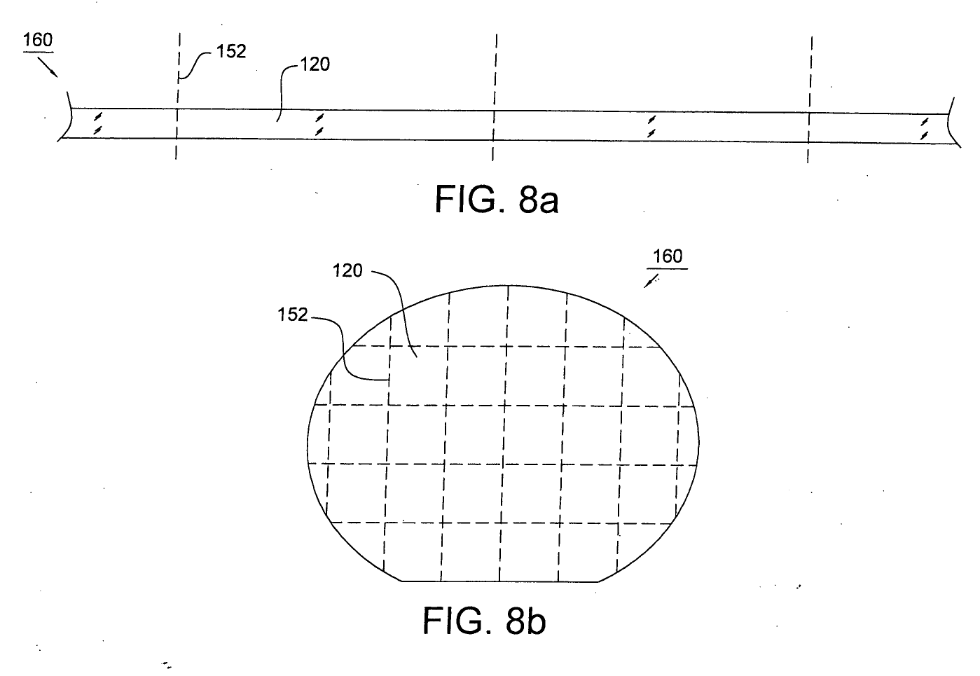

Referring to FIGS. 8a and 8b, a transparent substrate 160 includes a plurality of transparent substrate units 120, wherein the adjacent transparent substrate units 120 are separated by a plurality of dicing lines 152. In other words, the transparent substrate units 120 are corresponding to the chips 110.

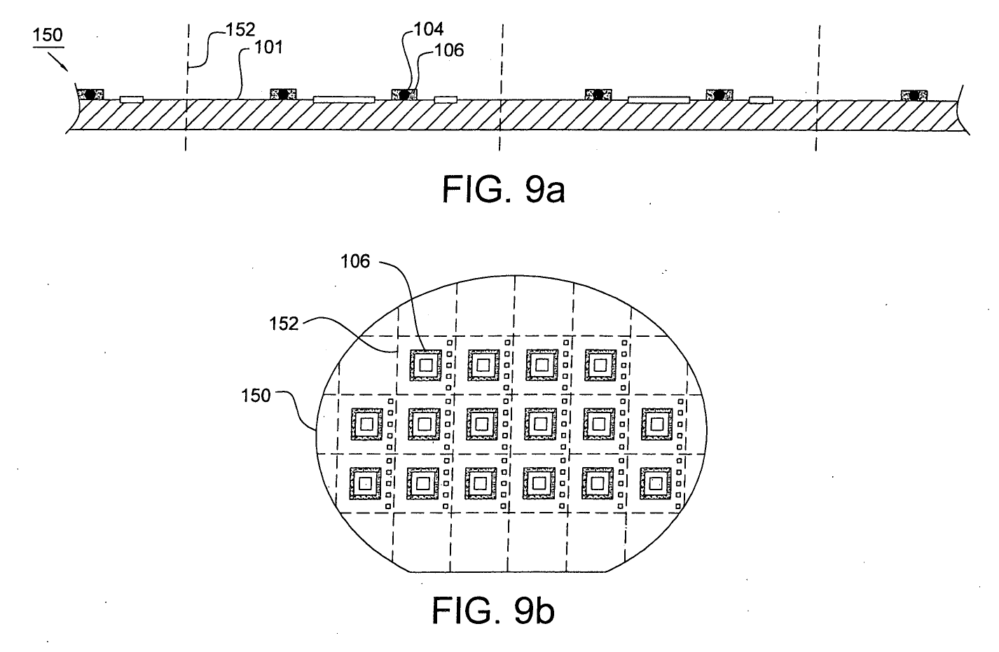

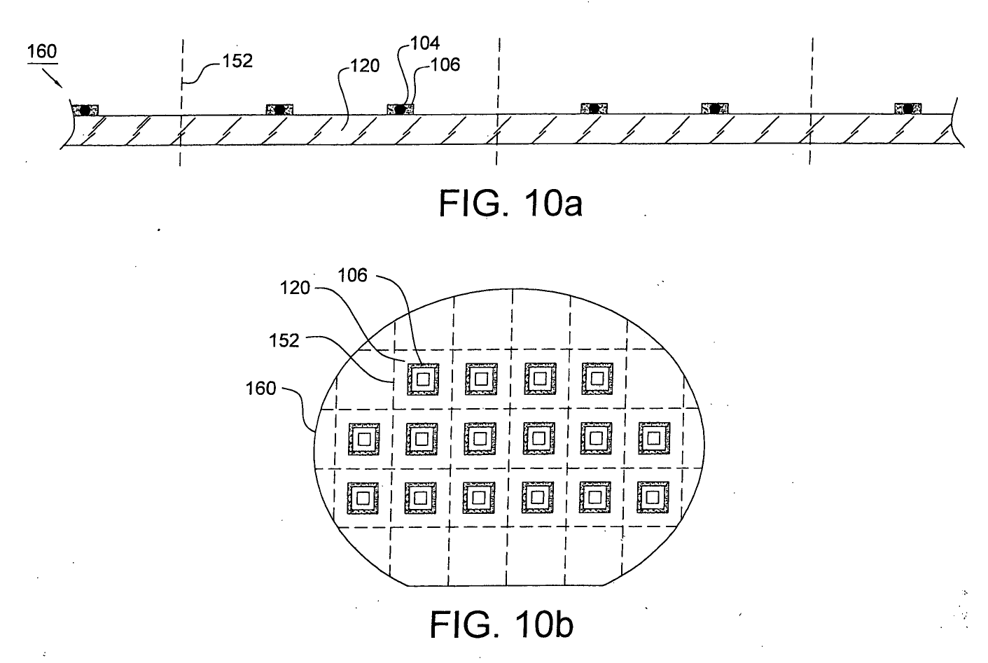

Referring to FIGS. 9a and 9b, a plurality of spacers 104 and adhesive 106 are disposed on the active surface 101 of the chip 110. It is apparent to one of ordinary skill in the art that a plurality of spacers 104 and adhesive 106 also are disposed on the transparent substrate unit 120, shown in FIGS. 10a and 10b. The spacers 104 can be intermixed to the adhesive 106.

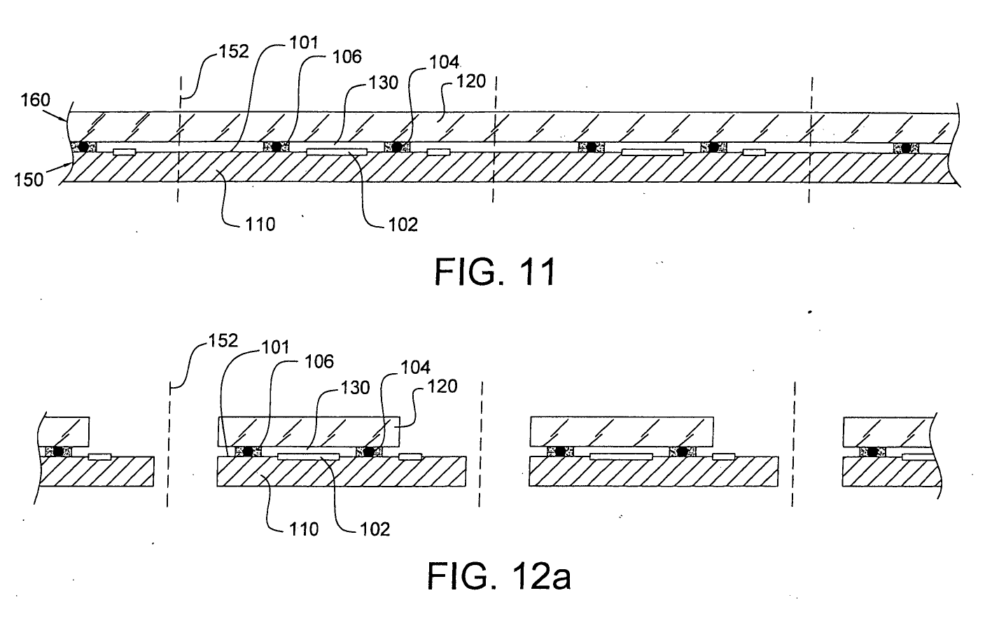

Referring to FIG. 11, the transparent substrate 160 is attached to the active surface 101 of the bottom substrate 150 by means of the adhesive 106. The spacers 104 are used for maintaining a predetermined gap between the transparent substrate unit 120 and the image sensor 102. The adhesive 106 encloses the image sensor 102, and the adhesive 106, the transparent substrate unit 120 and the chip 110 define an enclosing space 130. The enclosing space 130 can be closed (shown in FIG. 6a), wherein the enclosing space 130 can be in a state of similar vacuum or be filled with one of inert gas (e.g. Nitrogen), transparent solid material (e.g. UV resin), transparent partly solid material (e.g. liquid crystal), transparent liquid, adhesive and oil. The coefficients of expansion of the inert gas, transparent solid material, transparent partly solid material, transparent liquid, adhesive and oil approximate that of the transparent substrate unit 120 and/or the chip 110 if possible, or are low coefficients of expansion of material. More detailed, when the transparent substrate 160 is attached to the bottom substrate 150, the environment must be in a state of similar vacuum during manufacturing, such that the enclosing space 130 can be in a state of similar vacuum. Otherwise, before the transparent substrate 160 is attached to the bottom substrate 150, the enclosing space 130 can be filled with one of the inert gas, transparent solid material, transparent partly solid material, transparent liquid, adhesive and oil by using similar one drop fill (ODF) technology or vacuum suction technology. The spacers 104 are used for maintaining a predetermined gap between the transparent substrate unit 120 and the image sensor 102, thereby avoiding the non-uniform thickness of the stuff (one of the inert gas, transparent solid material, transparent partly solid material, transparent liquid, adhesive and oil) located between the transparent substrate unit 120 and the image sensor 102 during pressing.

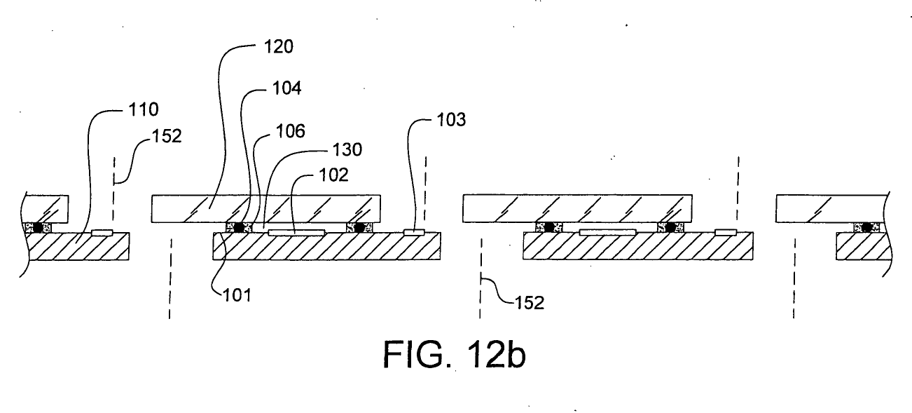

Referring to FIG. 12a, the bottom substrate 150 and the transparent substrate 160 are respectively diced along the dicing lines 152 for forming necessary shape, wherein the chip 110 and the transparent substrate unit 120 adhere to each other by means of the adhesive 106. Also, the enclosing space 130 can include at least one opening 132 and be filled with one of the inert gas, transparent solid material, transparent partly solid material, transparent liquid, adhesive and oil through the opening 132. The enclosing space 130 further include at least one seal material 134 formed on the opening 132 for sealing the opening 132, shown in FIGS. 6b, 6c and 6d.

Referring to FIG. 4a again, a flexible printed circuit board 122 is mounted and electrically connected to the pads 103 of the chip 110 by using an electrically conductive adhesive 124 so as to form the single image sensor package 100.

The bottom substrate 150 can be a transparent substrate, such as glass, acrylic resin, sapphire, ployimide or silicon wafer. The image sensor 102 can be a complementary metal-oxide semiconductor (CMOS) or charge coupled device (CCD), which made of semiconductor material or organic semiconductor material such as pentacene (C₂₂H₁₄).

Referring to FIG. 12b, the bottom substrate 150 and the transparent substrate 160 are respectively diced along dicing lines 152 with different locations to save the dicing time and cost. In other words, the bottom substrate 150 and the transparent substrate 160 are respectively interlaced in different direction for saving extra dicing steps.

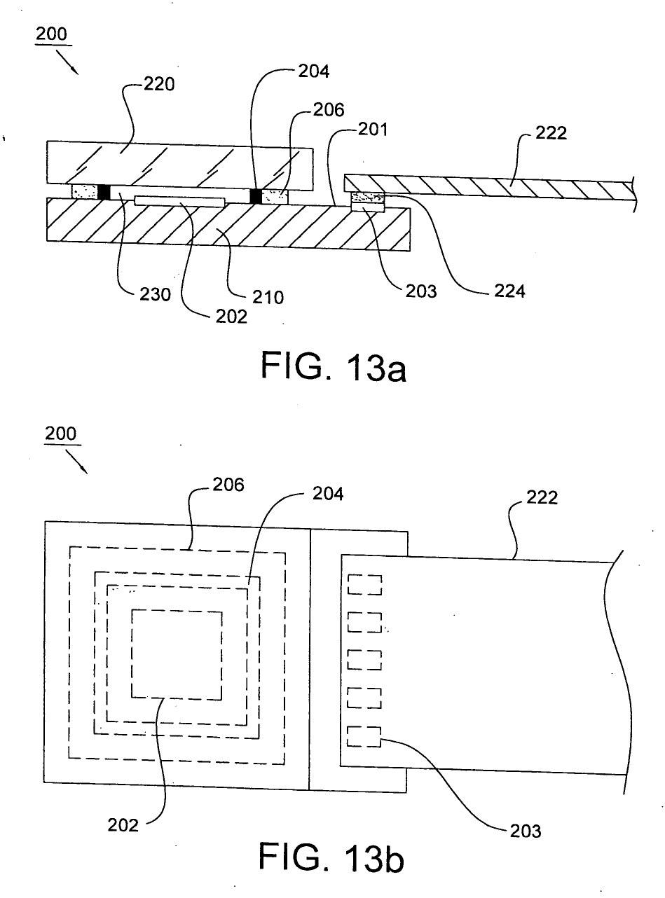

Referring to FIGS. 13a and 13b, they depict an image sensor package 200 according to the second embodiment of the present invention. The image sensor package 200 is similar to the image sensor package 100 wherein the similar elements are designated with the similar reference numerals. The image sensor package 200 includes a chip 210, which includes an active surface 201, an image sensor 202 disposed on the active surface 201, and a plurality of pads 203 disposed on the active surface 201, wherein the pads 203 and the image sensor 202 are at the same side. A transparent substrate unit 220 is disposed above the active surface 201 of the chip 210 and covers the image sensor 202. An annular spacer 204 is regarded as a plurality of spacers which are connected to one another and encloses the image sensor 202, and the annular spacer 204 is disposed between the transparent substrate unit 220 and the chip 210 for maintaining a predetermined gap defined between the transparent substrate unit 220 and the image sensor 202, wherein the predetermined gap is between 1 and 20 μm. An adhesive 206 is used for attaching the transparent substrate unit 220 to the chip 210. The pads 203 are mounted and electrically connected to a flexible printed circuit board 222 by using an electrically conductive adhesive 224. It is apparent to one of ordinary skill in the art that the pads 203 also are disposed on the active surface 201 and located along a peripheral edge of the image sensor 202. The image sensor 202 can be a complementary metal-oxide semiconductor (CMOS) or charge coupled device (CCD), which made of semiconductor material or organic semiconductor material such as pentacene (C₂₂H₁₄). The chip 210 can be made from a transparent substrate, such as glass, acrylic resin, sapphire, ployimide or silicon wafer. The transparent substrate unit 220 can be made of glass, acrylic resin, sapphire or ployimide materials.

The gap between the transparent substrate unit 220 and the image sensor 202 is controlled by the annular spacer 204 for maintaining the gap between the transparent substrate unit 120 and the image sensor 202 and further avoiding the affection of the optical effect of the image sensor and the emitting light. The annular spacer 204 can be made of photo-resist material. The annular spacer 204, the transparent substrate unit 220 and the chip 210 define an enclosing space 230. The enclosing space 230 can be closed, wherein the enclosing space 230 can be in a state of similar vacuum or be filled with one of inert gas (e.g. Nitrogen), transparent solid material (e.g. UV resin), transparent partly solid material (e.g. liquid crystal), transparent liquid, adhesive and oil. The expansion coefficients of the inert gas, transparent partly solid material, transparent liquid, adhesive and oil are selected to approximate that of the transparent substrate unit 220 and/or the chip 210 if possible, or are low expansion coefficients of material. Also, the enclosing space 230 can include at least one opening and seal material, wherein the seal material seals the opening.

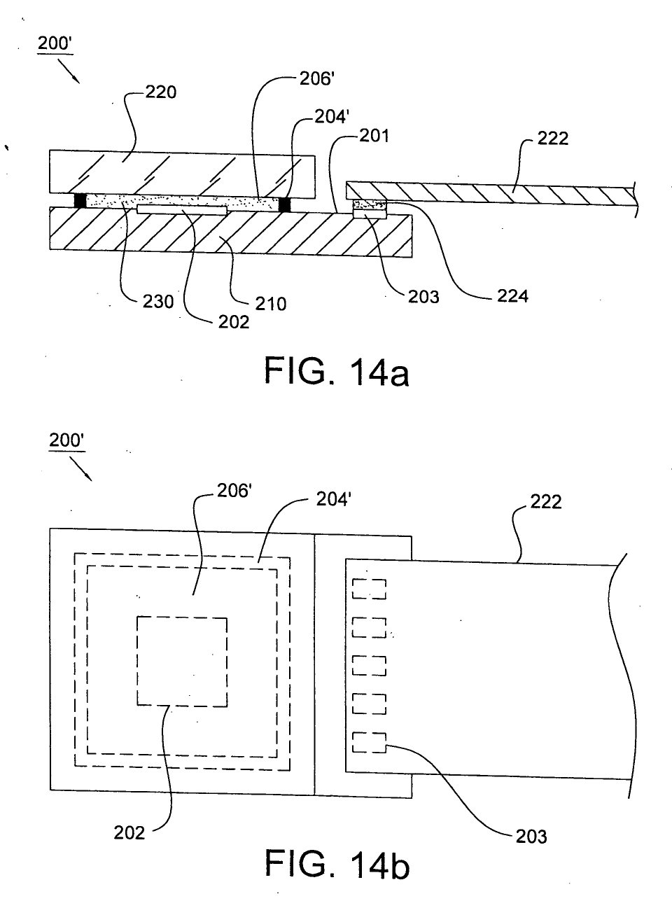

The adhesive 206 encloses the annular spacer 204 (shown in FIGS. 13a and 13b). Otherwise the enclosing space 230 is filled with the adhesive 206′ (shown in FIGS. 14a and 14b) and simultaneously the adhesive 206′ is transparent.

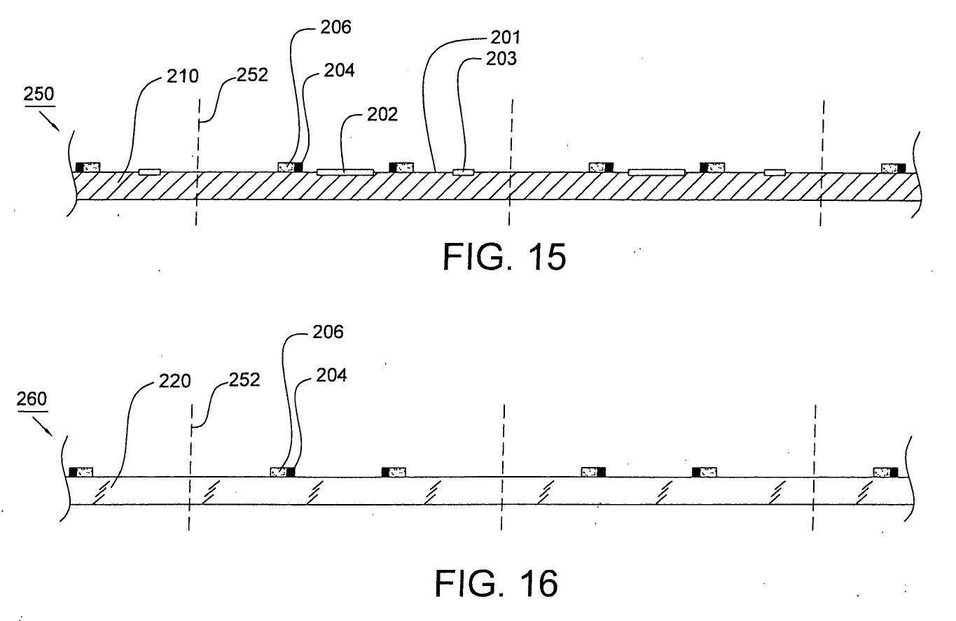

Referring to FIGS. 15 to 20b, they depict a method for manufacturing the image sensor package 200 according to the present invention.

A bottom substrate 250 includes a plurality of chips 210, wherein the adjacent chips 210 are separated by a plurality of dicing lines 252. Each chip 210 includes an active surface 201, an image sensor 202 disposed on the active surface 201, and a plurality of pads 203 disposed on the active surface 201, wherein the pads 203 and the image sensor 202 are at the same side. A transparent substrate 260 includes a plurality of transparent substrate units 220, wherein the adjacent transparent substrate units 220 are separated by a plurality of dicing lines 252. In other words, the transparent substrate units 220 are corresponding to the chips 210.

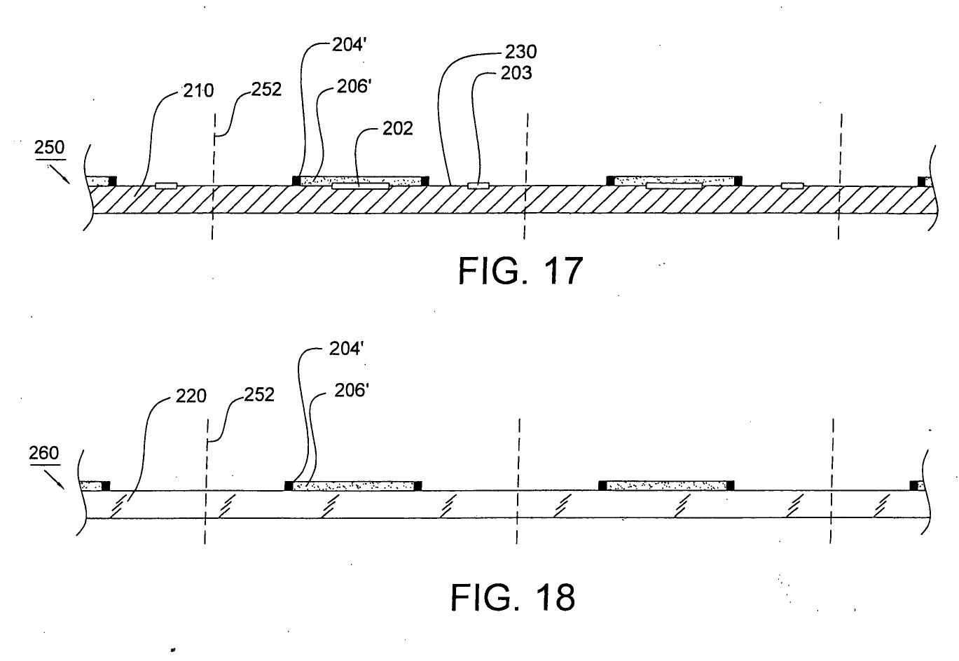

Referring to FIG. 15, a plurality of annular spacers 204 respectively enclose the image sensors 202 and are respectively disposed on the active surfaces 201 of the chips 210. For example, the annular spacer 204 can be made of photo-resist material and formed on the active surface 201 of the chip 210 by using photolithography and etching processes. An adhesive 206 is disposed on the active surface 201 of the chip 210 and encloses the annular spacer 204, shown in FIG. 15. Otherwise, the annular spacer 204 and adhesive 206 also are disposed on the transparent substrate unit 220, shown in FIG. 16. According to alternative embodiment of the present invention, the annular spacer 204′ and the chip 210 define a cavity and the cavity is filled with the adhesive 206′, shown in FIG. 17. Otherwise, the annular spacer 204′ and adhesive 206′ also are disposed on the transparent substrate unit 220, shown in FIG. 18.

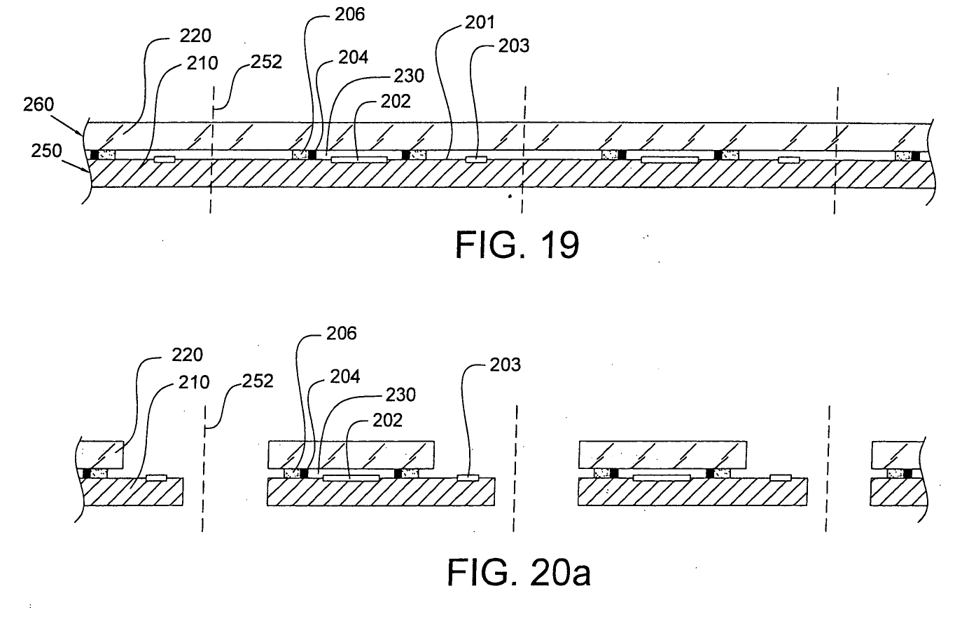

Referring to FIG. 19, the transparent substrate 260 is attached to the active surface 201 of the bottom substrate 250 by means of the adhesive 206. The annular spacer 204 is used for maintaining a predetermined gap between the transparent substrate unit 220 and the image sensor 202. The annular spacer 204, the transparent substrate unit 220 and the chip 210 define an enclosing space 230. The enclosing space 230 can be closed, wherein the enclosing space 230 can be in a state of similar vacuum or be filled with one of inert gas (e.g. Nitrogen), transparent solid material (e.g. UV resin), transparent partly solid material (e.g. liquid crystal), transparent liquid, adhesive and oil. The coefficients of expansion of the inert gas, transparent solid material, transparent partly solid material, transparent liquid, adhesive and oil approximate that of the transparent substrate unit 220 and/or the chip 210 if possible, or are low coefficients of expansion of material. More detailed, when the transparent substrate 260 is attached to the bottom substrate 250, the environment must be in a state of similar vacuum during manufacturing, such that the enclosing space 230 can be in a state of similar vacuum. Otherwise, before the transparent substrate 260 is attached to the bottom substrate 250, the enclosing space 230 can be filled with one of the inert gas, transparent solid material, transparent partly solid material, transparent liquid, adhesive and oil by using similar one drop fill (ODF) technology or vacuum suction technology. The annular spacer 204 is used for maintaining a predetermined gap between the transparent substrate unit 220 and the image sensor 202, thereby avoiding the non-uniform thickness of the stuff (one of the inert gas, transparent solid material, transparent partly solid material, transparent liquid, adhesive and oil) located between the transparent substrate unit 220 and the image sensor 202 during pressing.

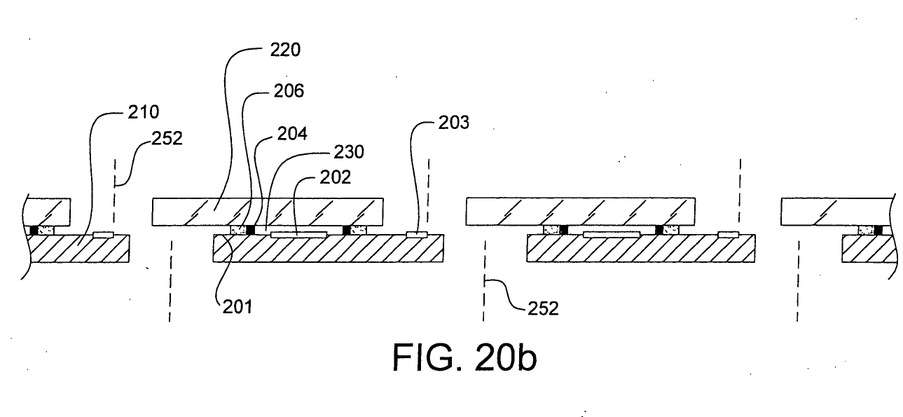

Referring to FIG. 20a, the bottom substrate 250 and the transparent substrate 260 are respectively diced along the dicing lines 252 for forming necessary shape, wherein the chip 210 and the transparent substrate unit 220 adhere to each other by means of the adhesive 206. Also, the enclosing space 230 can include at least one opening and be filled with one of the inert gas, transparent solid material, transparent partly solid material, transparent liquid, adhesive and oil through the opening. The enclosing space 230 further includes at least one seal material formed on the opening for sealing the opening.

Referring to FIG. 13a again, a flexible printed circuit board 222 is mounted and electrically connected to the pads 203 of the chip 210 by using an electrically conductive adhesive 224 so as to form the single image sensor package 200.

If the transparent substrate unit 220 and the adhesive 206 are omitted, the cavity defined by the annular spacer 204 and the chip 210 is filled with a transparent material for covering the image sensor 202, such as transparent adhesive or resin to be cured, thereby isolating the image sensor 202, avoiding the contact of external gas and moisture, and maintaining the optical property of the image sensor 202.

The bottom substrate 250 can be a transparent substrate, such as glass, acrylic resin, sapphire, ployimide or silicon wafer. The image sensor 202 can be a complementary metal-oxide semiconductor (CMOS) or charge coupled device (CCD), which made of semiconductor material or organic semiconductor material, such as pentacene (C₂₂H₁₄).

Referring to FIG. 20b, the bottom substrate 250 and the transparent substrate 260 are respectively diced along dicing lines 252 with different locations to save the dicing time and cost. In other words, the bottom substrate 250 and the transparent substrate 260 are respectively interlaced in different direction for saving extra dicing steps.

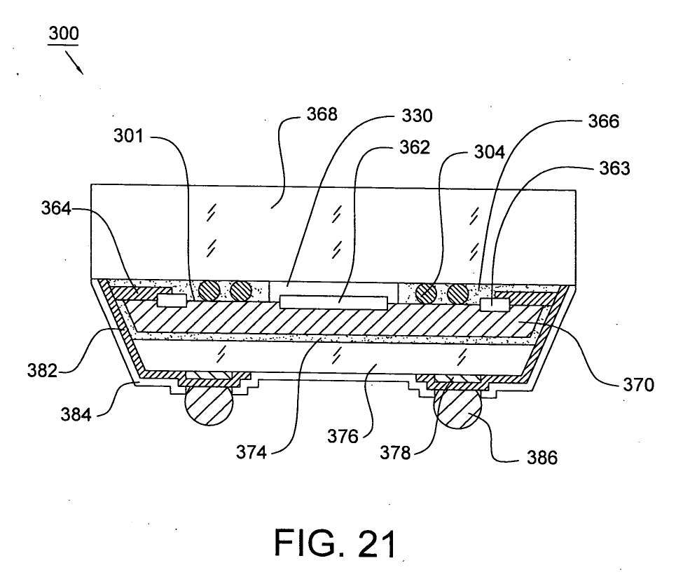

Referring to FIG. 21, it depicts an image sensor package 300 according to the third embodiment of the present invention. The image sensor package 300 includes a chip 370, which includes an active surface 301, an image sensor 362 disposed on the active surface 301, and a plurality of pads 363 disposed on the active surface 301. A pad extended layer 364 is disposed on the active surface 301 of the chip 370 and is electrically connected to the pads 363. A first glass substrate unit 368 is located on the active surface 301 of the chip 370 and covers the image sensor 362. The image sensor 362 can be a complementary metal-oxide semiconductor (CMOS) or charge coupled device (CCD), which made of semiconductor material or organic semiconductor material such as pentacene (C₂₂H₁₄). The first transparent substrate unit 368 can be made of glass, acrylic resin, sapphire or ployimide materials. The chip 370 can be made from a transparent substrate, such as glass, acrylic resin, sapphire, ployimide or silicon wafer. A plurality of spacers 304 are disposed between the first transparent substrate unit 368 and the chip 370 for maintaining a predetermined gap defined between the transparent substrate unit 368 and the image sensor 362, wherein the predetermined gap is between 1 and 20 μm. A first adhesive 366 is used for attaching the first transparent substrate unit 368 to the chip 370. A second transparent substrate unit 376 is located on a back surface of the chip 370. A second adhesive 374 is used for attaching the second transparent substrate unit 376 to the chip 370. A plurality of barrier pads 378 are disposed on the second transparent substrate 376. A plurality of conductive traces 382 on the edge of the chip 370, the second transparent substrate unit 376 and the barrier pads 378, wherein a T-contact is formed between the conductive trace 382 and the pad extended layer 364. A solder mask 384 is disposed on the conductive traces 382 and exposing out a part of conductive traces 382 located on the barrier pads 378. A plurality of solder balls 386 are disposed on the barrier pads 378, and are electrically connected to the conductive traces 382.

The gap between the first transparent substrate unit 368 and the image sensor 362 is controlled by the spacers 304 for maintaining the gap between the first transparent substrate unit 378 and the image sensor 362 and further avoiding the affection of the optical effect of the image sensor 362 and the emitting light. The spacers 304 can be intermixed to the first adhesive 366. The spacer's 304 can be in the shape of ball (shown in FIG. 21), fiber (not shown) or bar (not shown), which is made of glass, silicon oxide or plastic material.

The first adhesive 366 can be of annular shape for enclosing the image sensor 362, and the first adhesive 366, the first transparent substrate unit 368 and the chip 370 define an enclosing space 330. The enclosing space 330 can be closed, wherein the enclosing space 330 can be in a state of similar vacuum or be filled with one of inert gas (e.g. Nitrogen), transparent solid material (e.g. UV resin), transparent partly solid material (e.g. liquid crystal), transparent liquid, adhesive and oil. The expansion coefficients of the inert gas, transparent partly solid material, transparent liquid, adhesive and oil are selected to approximate that of the first transparent substrate unit 368 and/or the chip 370 if possible, or are low expansion coefficients of material.

According to a method for manufacturing the image sensor package 300 of the present invention, a bottom substrate includes a plurality of chips 370, wherein the adjacent chips 370 are separated by a plurality of dicing lines. Each chip 370 includes an active surface 301, an image sensor 362 disposed on the active surface 301, and a plurality of pads 363 disposed on the active surface 301. A pad extended layer 364 is disposed on the active surface 301 of the chip 370 and is electrically connected to the pads 363 by using photolithography and etching processes of redistribution layer (RDL).

A first transparent substrate includes a plurality of first transparent substrate units 368, wherein the adjacent first transparent substrate units 368 are separated by a plurality of dicing lines. In other words, the first transparent substrate units 368 are corresponding to the chips 370.

A plurality of spacers 304 and first adhesive 366 are disposed on the active surface 301 of the chip 370. It is apparent to one of ordinary skill in the art that a plurality of spacers 304 and first adhesive 366 also are disposed on the first transparent substrate unit 368. The spacers 304 can be intermixed to the first adhesive 366.

The first transparent substrate is attached to the active surface 301 of the bottom substrate by means of the first adhesive 366. The spacers 304 are used for maintaining a predetermined gap between the transparent substrate unit 368 and the image sensor 362. The first adhesive 366 encloses the image sensor 362, and the first adhesive 366, the first transparent substrate unit 368 and the chip 370 define an enclosing space 330. The enclosing space 330 can be closed, wherein the enclosing space 330 can be in a state of similar vacuum or be filled with one of inert gas (e.g. Nitrogen), transparent solid material (e.g. UV resin), transparent partly solid material (e.g. liquid crystal), transparent liquid, adhesive and oil. The coefficients of expansion of the inert gas, transparent solid material, transparent partly solid material, transparent liquid, adhesive and oil approximate that of the first transparent substrate unit 368 and/or the chip 370 if possible, or are low coefficients of expansion of material. The spacers 304 are used for maintaining a predetermined gap between the transparent substrate unit 368 and the image sensor 362, thereby avoiding the non-uniform thickness of the stuff (one of the inert gas, transparent solid material, transparent partly solid material, transparent liquid, adhesive and oil) located between the transparent substrate unit 368 and the image sensor 362 during pressing.

A back surface of the bottom substrate is grinded by using a mechanical wheel or a chemical mechanical polishing (CMP) process, and the bottom substrate is grinded to a predetermined thickness. Also, a first notch is formed in the back surface of the bottom substrate for exposing out the pad extended layer 364. A second adhesive 374 is disposed on the back surface of the bottom substrate, and the first notch is filled with the second adhesive 374. A second transparent substrate is attached to the back surface of the bottom substrate by using the second adhesive 374, wherein the second transparent substrate includes a plurality of second transparent substrate unit 376. A plurality of barrier pads 378 are formed on the second transparent substrate unit 376 by using film deposition, photolithography and etching processes. A second notch is formed in the second transparent substrate for passing through the bottom substrate and the first and second adhesive 366, 374 and exposing out the pad extended layer 364. A plurality of conductive traces 382 are formed on the second notch and the barrier pads 378 by using film deposition, photolithography and etching processes, and are respectively electrically connected to the pad extended layer 364. A solder mask 384 is formed on the conductive traces 382 and exposing out a part of conductive traces 382 located on the barrier pads 378. A plurality of solder balls 386 are disposed on the barrier pads 378, wherein the solder balls 386 are electrically connected to the conductive traces 382.

A single image sensor package 300, shown in FIG. 21, is formed by respectively dicing the second transparent substrate, the bottom substrate and the first transparent substrate along a plurality of dicing lines of the second glass substrate.

The bottom substrate can be a transparent substrate, such as glass, acrylic resin, sapphire, ployimide or silicon wafer. The image sensor 362 can be a complementary metal-oxide semiconductor (CMOS) or charge coupled device (CCD), which made of semiconductor material or organic semiconductor material such as pentacene (C₂₂H₁₄).

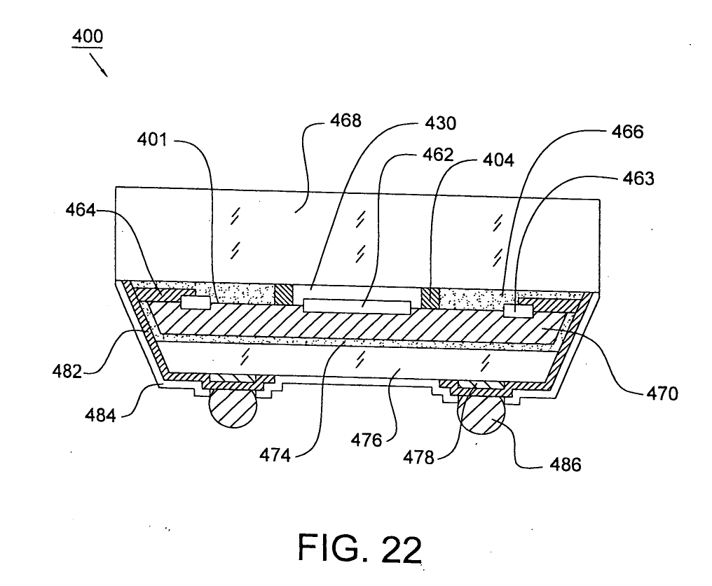

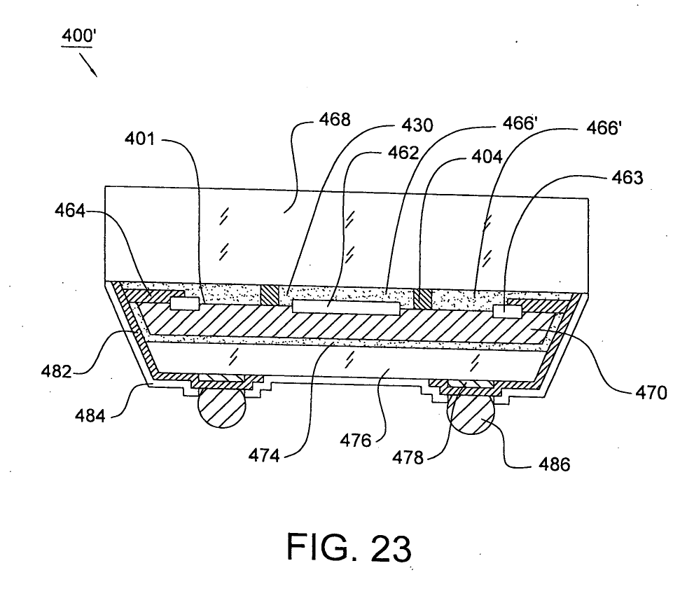

Referring to FIG. 22, it depicts an image sensor package 400 according to the fourth embodiment of the present invention. The image sensor package 400 is similar to the image sensor package 300 wherein the similar elements are designated with the similar reference numerals. An annular spacer 404 is regarded as a plurality of spacers which are connected to one another and encloses the image sensor 462, and the annular spacer 404 is disposed between the first transparent substrate unit 468 and the chip 470 for maintaining a predetermined gap defined between the first transparent substrate unit 468 and the image sensor 462, wherein the predetermined gap is between 1 and 20 μm. The annular spacer 404 can be made of photo-resist material. The annular spacer 404, the first transparent substrate unit 468 and the chip 470 define an enclosing space 430. The enclosing space 430 can be closed, wherein the enclosing space 430 can be in a state of similar vacuum or be filled with one of inert gas (e.g. Nitrogen), transparent solid material (e.g. UV resin), transparent partly solid material (e.g. liquid crystal), transparent liquid, adhesive and oil. The expansion coefficients of the inert gas, transparent partly solid material, transparent liquid, adhesive and oil are selected to approximate that of the first transparent substrate unit 468 and/or the chip 470 if possible, or are low expansion coefficients of material. The first adhesive 466 encloses the annular spacer 404 (shown in FIG. 22). Otherwise the enclosing space 430 is filled with the first adhesive 466′ (shown in FIG. 23) and simultaneously the first adhesive 466′ is transparent.

According to a method for manufacturing the image sensor package 400 of the present invention, a bottom substrate includes a plurality of chips 470, which the adjacent chips 470 are separated by a plurality of dicing lines. Each chip 470 includes an active surface 401, an image sensor 462 disposed on the active surface 401, and a plurality of pads 403 disposed on the active surface 401. A pad extended layer 464 is disposed on the active surface 401 of the chip 470 and is electrically connected to the pads 463.

A first transparent substrate includes a plurality of first transparent substrate units 468, wherein the adjacent first transparent substrate units 468 are separated by a plurality of dicing lines. In other words, the first transparent substrate units 468 are corresponding to the chips 470.

A plurality of annular spacers 404 respectively enclose the image sensors 462 and are respectively disposed on the active surfaces 401 of the chips 470. For example, the annular spacer 404 can be made of photo-resist material and formed on the active surface 401 of the chip 470 by using photolithography and etching processes. A first adhesive 466 is disposed on the active surface 401 of the chip 470 and encloses the annular spacer 404. Otherwise, the annular spacer 404 and first adhesive 466 also are disposed on the first transparent substrate unit 468, shown in FIG. 22. According to alternative embodiment of the present invention, the annular spacer 404 and the chip 470 define a cavity and the cavity is filled with the first adhesive 466′, shown in FIG. 23. Otherwise, the annular spacer 404 and first adhesive 466′ also are disposed on the first transparent substrate unit 468, shown in FIG. 23.

The first transparent substrate is attached to the active surface 401 of the bottom substrate by means of the first adhesive 466. The gap between the first transparent substrate unit 468 and the image sensor 462 is controlled by the spacers 404 for maintaining the gap between the first transparent substrate unit 468 and the image sensor 462. The annular spacer 404, the first transparent substrate unit 468 and the chip 470 define an enclosing space 430. The enclosing space 430 can be closed, wherein the enclosing space 430 can be in a state of similar vacuum or be filled with one of inert gas (e.g. Nitrogen), transparent solid material (e.g. UV resin), transparent partly solid material (e.g. liquid crystal), transparent liquid, adhesive and oil. The coefficients of expansion of the inert gas, transparent solid material, transparent partly solid material, transparent liquid, adhesive and oil approximate that of the first transparent substrate unit 468 and/or the chip 470 if possible, or are low coefficients of expansion of material. The annular spacer 404 is used for maintaining a predetermined gap between the first transparent substrate unit 468 and the image sensor 462, thereby avoiding the non-uniform thickness of the stuff (one of the inert gas, transparent solid material, transparent partly solid material, transparent liquid, adhesive and oil) located between the first transparent substrate unit 468 and the image sensor 462 during pressing.

The bottom substrate is grinded to a predetermined thickness. Also, a first notch is formed in a back surface of the bottom substrate for exposing out the pad extended layer 464. A second adhesive 474 is disposed on the back surface of the bottom substrate, and the first notch is filled with the second adhesive 474. A second transparent substrate is attached to the back surface of the bottom substrate by using the second adhesive 474, wherein the second transparent substrate includes a plurality of second transparent substrate unit 476.

A plurality of barrier pads 478 are formed on the second transparent substrate unit 476. A second notch is formed in the second transparent substrate for passing through the bottom substrate and the first and second adhesive 466, 474 and exposing out the pad extended layer 464. A plurality of conductive traces 482 are formed on the second notch and the barrier pads 478, and are respectively electrically connected to the pad extended layer 464. A solder mask 484 is formed on the conductive traces 482 and exposing out a part of conductive traces 482 located on the barrier pads 478.

A single image sensor package 400, shown in FIG. 22 is formed by respectively dicing the second transparent substrate, the bottom substrate and the first transparent substrate along a plurality of dicing lines of the second glass substrate.

The bottom substrate can be a transparent substrate, such as glass, acrylic resin, sapphire, ployimide or silicon wafer. The image sensor 462 can be a complementary metal-oxide semiconductor (CMOS) or charge coupled device (CCD), which made of semiconductor material or organic semiconductor material such as pentacene (C₂₂H₁₄). The second transparent substrate unit 476 can be made of glass, acrylic resin or sapphire materials.

According to the image sensor package and the method for manufacturing the same of the present invention, the image sensor package can be applied to the mass production with wafer lever, such that the cost of the packaging process is decreased, the reliability of package is increased, and the volume of the image sensor package cannot be enlarged. Furthermore, the gap between the transparent substrate unit and the image sensor is controlled by the spacer of the image sensor package of the present invention for maintaining the gap between the transparent substrate unit and the image sensor and further avoiding the affection of the optical effect of the image sensor and the emitting light. The spacers of the image sensor package of the present invention are used for maintaining a predetermined gap between the transparent substrate unit and the image sensor, thereby avoiding the non-uniform thickness of the stuff (one of the inert gas, transparent solid material, transparent partly solid material, transparent liquid, adhesive and oil) located between the transparent substrate unit and the image sensor during pressing. In addition, according to the image sensor package of the present invention, the gap between the transparent substrate unit and the image sensor can be in a state of similar vacuum or be filled with transparent liquid, thereby avoiding the expansion of residual air in the gap between the transparent substrate unit and the image sensor during heating and further avoiding the crack of the image sensor package.

The image sensor of the image sensor package of the present invention can be replaced with solar energy plate, light sensor, etc.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A sensor package, comprising:
a chip including a surface and a sensor disposed on the surface;
a transparent substrate unit facing the surface;
at least one spacer disposed between the transparent substrate unit and the chip for maintaining a predetermined gap defined between the transparent substrate unit and the sensor; and
an adhesive for attaching the transparent substrate unit to the chip.

2. The sensor package as claimed in claim 1, wherein the predetermined gap can be between 1 and 20 μm.

3. The sensor package as claimed in claim 1, wherein the adhesive, the transparent substrate unit and the chip define a first enclosing space.

4. The sensor package as claimed in claim 3, wherein the first enclosing space is closed.

5. The sensor package as claimed in claim 4, wherein the first enclosing space is in a state of similar vacuum.

6. The sensor package as claimed in claim 4, wherein the first enclosing space is filled with a stuff being selected from the group consisting of inert gas, transparent solid material, transparent partly solid material, transparent liquid, adhesive and oil.

7. The sensor package as claimed in claim 3, wherein the first enclosing space includes at least one first opening.

8. The sensor package as claimed in claim 7, wherein the first enclosing space includes at least one first seal material for sealing the first opening.

9. The sensor package as claimed in claim 1, wherein the spacer is intermixed to the adhesive.

10. The sensor package as claimed in claim 1, wherein the spacer is in the shape of being selected from the group consisting of ball, fiber and bar.

11. The sensor package as claimed in claim 1, wherein the spacer is made of being selected from the group consisting of glass, silicon oxide and plastic material.

12. The sensor package as claimed in claim 1, wherein the plurality of spacers are connected to one another for forming an annular spacer and enclose the image sensor, and the annular spacer, the transparent substrate unit and the chip define a second enclosing space.

13. The sensor package as claimed in claim 12, wherein the second enclosing space is closed.

14. The sensor package as claimed in claim 13, wherein the second enclosing space is in a state of similar vacuum.

15. The sensor package as claimed in claim 13, wherein the second enclosing space is filled with a stuff being selected from the group consisting of inert gas, transparent solid material, transparent partly solid material, transparent liquid, adhesive and oil.

16. The sensor package as claimed in claim 12, wherein the adhesive encloses the annular spacer.

17. The sensor package as claimed in claim 12, wherein the second enclosing space includes at least one second opening.

18. The sensor package as claimed in claim 17, wherein the second enclosing space includes at least one second seal material for sealing the opening.

19. The sensor package as claimed in claim 12, wherein the annular spacer is made of photo-resist material.

20. A sensor package, comprising:
a chip including a surface and a sensor disposed on the surface;
a transparent substrate unit facing the surface; and
an adhesive enclosing the sensor for attaching the transparent substrate unit to the chip, wherein the adhesive, the transparent substrate unit and the chip define an enclosing space, and the enclosing space includes at least one opening and seal material for sealing the opening.

21. The sensor package as claimed in claim 20, wherein the enclosing space is in a state of similar vacuum.

22. The sensor package as claimed in claim 20, wherein the enclosing space is filled with a stuff being selected from the group consisting of inert gas, transparent solid material, transparent partly solid material, transparent liquid, adhesive and oil.

23. A sensor package, comprising:
a chip including a surface and a sensor disposed on the surface;
an annular spacer disposed on the surface and enclosing the sensor; and
a transparent material for covering the sensor of the chip.

24. The sensor package as claimed in claim 23, wherein the annular spacer is made of photo-resist material.

25. A sensor package, comprising:
a bottom substrate comprising a plurality of chips, which each includes a surface and a sensor disposed on the surface;
a transparent substrate comprising a plurality of transparent substrate units corresponding to the chips, wherein the transparent substrate unit faces the surface;
at least on spacer disposed between the transparent substrate unit and the chip for maintaining a predetermined gap defined between the transparent substrate unit and the sensor; and
an adhesive for attaching the transparent substrate unit to the chip.

26. A method for manufacturing a sensor package, comprising the following steps of:
providing a bottom substrate comprising a plurality of chips, which each includes a surface and a sensor disposed on the surface;
providing a transparent substrate comprising a plurality of transparent substrate units corresponding to the chips, wherein the transparent substrate unit faces the surface;
disposing a plurality of spacers and adhesive between the transparent substrate and the bottom substrate; and
attaching the transparent substrate to the surface of the bottom substrate, wherein the spacers are used for maintaining a predetermined gap defined between the transparent substrate unit and the sensor.
